(19) United States
(12) Patent Application Publication
(10) Pub. No.: US 2026/0367108 A1
(43) Pub. Date: Nov. 19, 2026

(54) CONDUCTIVE CONTACT UNIT

(71) Applicant: NHK Spring Co., Ltd., Yokohama-shi (JP)

(72) Inventor: Yukihiro Isono, Kanagawa (JP)

(73) Assignee: NHK Spring Co., Ltd., Yokohama-shi (JP)

(21) Appl. No.: 19/667,915

(22) Filed: May 5, 2026

(30) Foreign Application Priority Data
May 14, 2025 (JP) 2025-081211

(51) Int. Cl. G01R 1/04; G01R 1/067; G01R 1/073

(52) U.S. Cl. CPC G01R 1/045; G01R 1/0466; G01R 1/06761; G01R 1/06772; G01R 1/07307

(57) ABSTRACT

There is provided a conductive contact unit that includes: a signal conductive contact configured to input and output signals from and to a predetermined circuit structure; and a conductive contact holder configured to accommodate the signal conductive contact and form, together with the signal conductive contact, a coaxial structure, wherein the conductive contact holder includes: a holder substrate that is conductive and has, formed therein, a hole through which the signal conductive contact is insertable; a holding member that is accommodated in the hole, has, formed therein, a holding hole to hold the signal conductive contact, and is insulating; and an insulating member configured to cover all external surfaces of the holder substrate.

This application is based upon and claims the benefit of priority of the prior Japanese Patent Application No. 2025-081211, filed on May 14, 2025, the entire contents of which are incorporated herein by reference.

### BACKGROUND

The present disclosure relates to conductive contact units.

In the technical field relating to electrical characteristic testing of semiconductor integrated circuits, techniques relating to a conductive contact unit having a plurality of conductive contacts disposed so as to correspond to external contact electrodes of a semiconductor integrated circuit have been known conventionally. Such a conductive contact unit is configured to include a plurality of conductive contacts, a conductive contact holder having openings formed therein to accommodate the conductive contacts, and a test circuit electrically connected to the conductive contacts (see, for example, Japanese Patent No. 7430253). According to Japanese Patent No. 7430253, to improve high frequency characteristics, insulating members are disposed at both ends of holder holes which are formed in the holder and through which the conductive contacts are inserted, and the conductive contacts are supported by these insulating members.

### SUMMARY

There has been a demand for further improvement in high frequency characteristics of conductive contact units.

According to an aspect of an embodiment, there is provided a conductive contact unit including: a signal conductive contact configured to input and output signals from and to a predetermined circuit structure; and a conductive contact holder configured to accommodate the signal conductive contact and form, together with the signal conductive contact, a coaxial structure, wherein the conductive contact holder includes: a holder substrate that is conductive and has, formed therein, a hole through which the signal conductive contact is insertable; a holding member that is accommodated in the hole, has, formed therein, a holding hole to hold the signal conductive contact, and is insulating; and an insulating member configured to cover all external surfaces of the holder substrate.

The object and advantages of the disclosure will be realized and attained by means of the elements and combinations particularly pointed out in the claims.

It is to be understood that both the foregoing general description and the following detailed description are exemplary and explanatory and are not restrictive of the disclosure, as claimed.

### BRIEF DESCRIPTION OF THE DRAWINGS

FIG. 1 is a schematic diagram illustrating an overall configuration of a conductive contact unit according to an embodiment;

FIG. 2 is a perspective view illustrating a configuration of a conductive contact holder and conductive contacts both included in the conductive contact unit according to the embodiment;

FIG. 3 is a partial sectional view illustrating the configuration of the conductive contact holder and the conductive contacts both included in the conductive contact unit according to the embodiment;

FIG. 4 is a schematic diagram illustrating electrical interaction between the conductive contacts and the conductive contact holder during use of the conductive contact unit according to the embodiment;

FIG. 5 is a first diagram illustrating a method of manufacturing the conductive contact holder according to the embodiment;

FIG. 6 is a second diagram illustrating the method of manufacturing the conductive contact holder according to the embodiment;

FIG. 7 is a third diagram illustrating the method of manufacturing the conductive contact holder according to the embodiment;

FIG. 8 is a first diagram illustrating a method of manufacturing a conventional conductive contact holder;

FIG. 9 is a second diagram illustrating the method of manufacturing the conventional conductive contact holder;

FIG. 10 is a partial sectional view illustrating a configuration of a conductive contact holder according to a first modified example of the embodiment; and

FIG. 11 is a partial sectional view illustrating a configuration of a conductive contact holder according to a second modified example of the embodiment.

### DETAILED DESCRIPTION

An embodiment will be described in detail hereinafter, together with the drawings. The present disclosure is not to be limited by the following embodiment. The drawings referred to in the following description schematically illustrate shapes, sizes, and positional relations to merely enable the present disclosure to be understood, and the present disclosure is therefore not to be limited to the shapes, sizes, and positional relations exemplified by the drawings.

A conductive contact unit according to an embodiment will be described first. The conductive contact unit according to the embodiment is for inputting and outputting electrical signals from and to, supplying power to, and supplying a ground potential to a predetermined circuit structure, such as a semiconductor integrated circuit. In particular, to stably supply the ground potential, the conductive contact unit is configured to have a ground conductive contact for supplying the ground potential and a conductive contact holder formed of a conductive material electrically connected to each other. In the present specification, the term "coaxial structure" refers to a coaxial structure in which a central axis of a conductive contact for signals coincides with a central axis of an inner surface of a cylindrical ground.

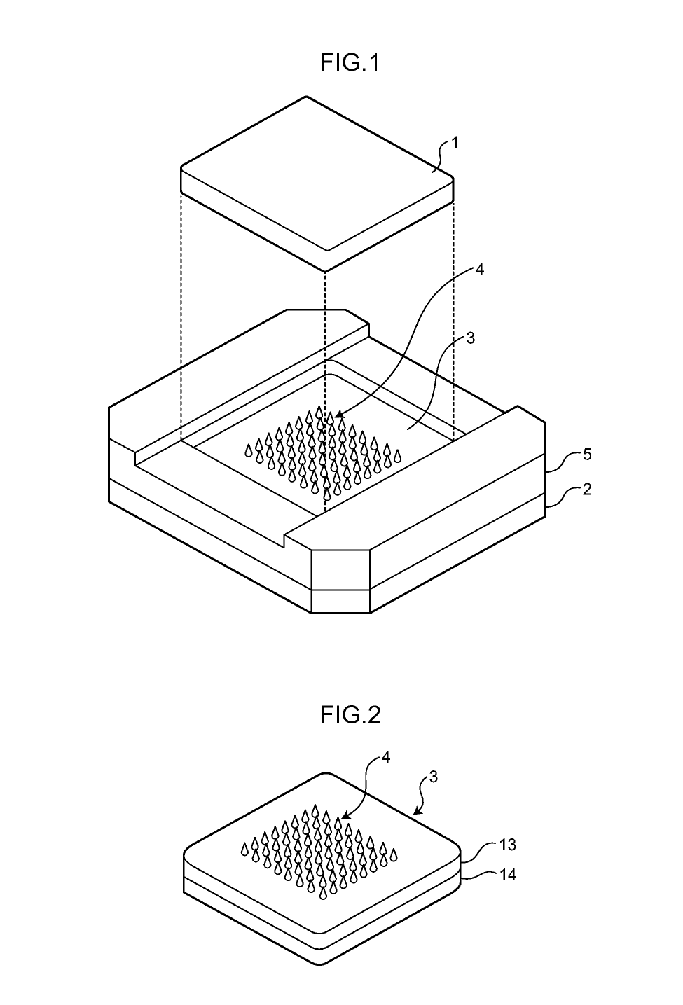

FIG. 1 is a schematic diagram illustrating a structure of the conductive contact unit according to the embodiment. As illustrated in FIG. 1, the conductive contact unit according to the embodiment includes: a circuit board 2 including a circuit that generates a signal to be supplied to a semiconductor integrated circuit 1; a conductive contact holder 3 arranged on the circuit board 2 and including predetermined openings (not illustrated in FIG. 1); and conductive contacts 4 accommodated in the openings of the conductive contact holder 3. A holder member 5 for preventing positional displacement of the semiconductor integrated circuit 1 during use is arranged on the circuit board 2 and on an outer periphery of the conductive contact holder 3.

The circuit board 2 includes a test circuit for testing electrical characteristics of the semiconductor integrated circuit 1 to be tested. The circuit board 2 is configured to have electrodes (not illustrated in FIG. 1) arranged on a surface thereof that come into contact with the conductive contact holder 3, the electrodes being for electrically connecting the built-in circuit to the conductive contacts 4.

The conductive contact holder 3 is for accommodating the conductive contacts 4. Specifically, the conductive contact holder 3 includes: a holder substrate 11 formed of a conductive material, such as metal; and an insulating member 13 that covers surfaces of the holder substrate 11. The holder substrate 11 has a structure having, formed therein, openings in a region corresponding to locations where the conductive contacts 4 are disposed, the openings accommodating the conductive contacts 4.

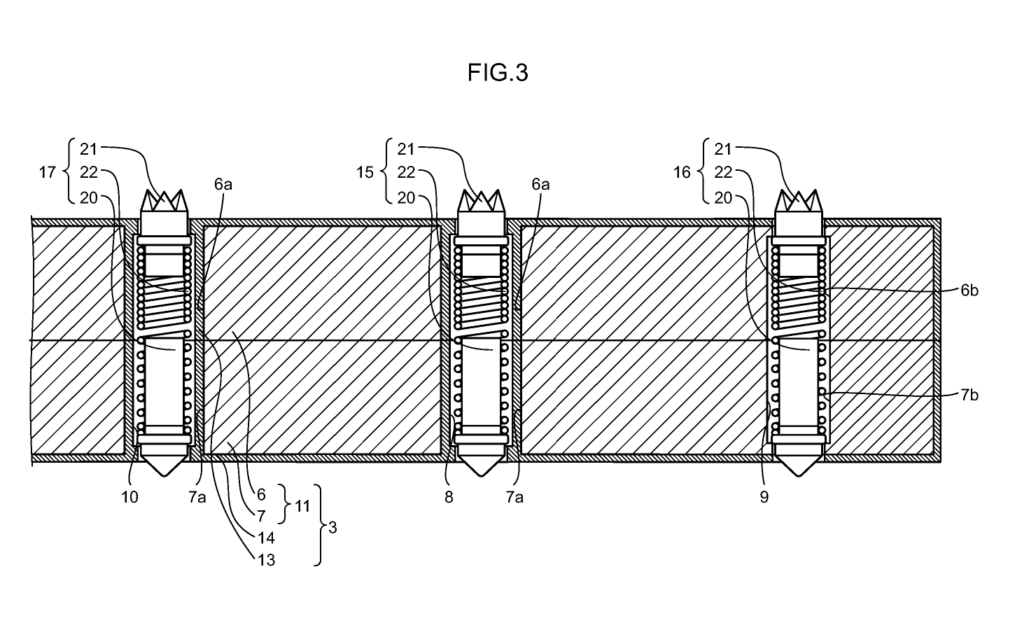

FIG. 2 is a perspective view illustrating a configuration of a conductive contact holder and conductive contacts both included in the conductive contact unit according to the embodiment. FIG. 3 is a partial sectional view illustrating a detailed configuration of the conductive contact holder 3 and the conductive contacts 4.

The conductive contacts 4 are for electrically connecting the circuit included in the circuit board 2 and the semiconductor integrated circuit 1. The conductive contacts 4 are broadly classified into three types according to types of signals to be supplied to the semiconductor integrated circuit 1. Specifically, the conductive contacts 4 include: a signal conductive contact 15 for inputting and outputting electrical signals from and to the semiconductor integrated circuit 1; a ground conductive contact 16 for supplying a ground potential to the semiconductor integrated circuit 1; and a power supply conductive contact 17 for supplying power to the semiconductor integrated circuit 1. Hereinafter, a signal conductive contact, a ground conductive contact, and a power supply conductive contact will be collectively referred to as "conductive contacts", and each of them will be referred to by its name when individually mentioned.

Structures of conductive contacts will be described next. The signal conductive contact 15, the ground conductive contact 16, and the power supply conductive contact 17 have different functions, but their specific structures may be regarded as similar. Therefore, the structure of the signal conductive contact 15 will be described hereinafter representatively.

The signal conductive contact 15 includes: a needle-like member 20 for electrically connecting to an electrode provided on the circuit board 2; a needle-like member 21 for electrically connecting to a connection electrode provided on the semiconductor integrated circuit 1 during use; and a spring member 22 provided between the needle-like member 20 and the needle-like member 21, the spring member 22 being for electrically connecting the needle-like members 20 and 21 and for expanding and contracting the signal conductive contact 15 in a longitudinal direction. The needle-like member 20, the needle-like member 21, and the spring member 22 are configured to be: accommodated in a first opening 8 such that their axial lines coincide with an axial line of the first opening 8; and movable in an axial direction. "Coincidence of axial lines" includes deviations caused by manufacturing tolerances. A needle-like member (the needle-like member 21 in the embodiment) for electrically connecting to a connection electrode provided on the semiconductor integrated circuit 1 during use corresponds to a first plunger, and a needle-like member (the needle-like member 20 in the embodiment) for electrically connecting to an electrode provided on the circuit board 2 corresponds to a second plunger.

The needle-like member 20 is for electrically connecting to the electrode arranged on the surface of the circuit board 2. Specifically, the needle-like member 20 has a sharp tip toward the circuit board 2 and the sharp tip is configured to contact the electrode provided on the circuit board 2. Because the needle-like member 20 is movable in the axial direction by expansion and contraction of the spring member 22, the needle-like member 20 is capable of optimally contacting the electrode provided on the circuit board 2 in accordance with irregularities on the electrode and contacting the electrode with reduced contact resistance under a pressing force exerted by the spring member 22 in an expansion direction thereof.

The needle-like member 20 also has a flange portion protruding in a direction perpendicular to the axial line, as illustrated in FIG. 3. As described above, because the first opening 8 is formed to have a smaller inner diameter near a lower surface of the holder substrate 11, as the needle-like member 20 moves downward, the flange portion and the insulating member 13 provided on an inner surface of the first opening 8 abut against each other and the needle-like member 20 is thereby prevented from coming off.

The needle-like member 21 is for electrically connecting to the connection electrode provided on the semiconductor integrated circuit 1 during use of the conductive contact unit according to the embodiment. Specifically, the needle-like member 21 is configured to come into contact with the connection electrode at an end portion thereof toward the semiconductor integrated circuit 1. The needle-like member 21 is movable in the axial direction by expansion and contraction of the spring member 22, similarly to the needle-like member 20, and has a flange portion protruding in a direction perpendicular to the axial line. By being configured as described above, the conductive contacts are structured to: electrically connect the electrodes provided on the circuit board 2 and the connection electrodes provided on the semiconductor integrated circuit 1; and be prevented by the flange portions from coming off.

Furthermore, the conductive contact holder 3 includes: a first substrate 6 and a second substrate 7 that are formed of a conductive material; the insulating member 13; and an insulating member 14.

The holder substrate 11 (the first substrate 6 and the second substrate 7) is formed of a conductive material and functions as a main member of the conductive contact holder 3.

The first substrate 6 and the second substrate 7 are joined together using, for example, a screw member. The first substrate 6 has one or more holes 6a and 6b formed therein and penetrating the first substrate 6. The second substrate 7 has one or more holes 7a and 7b formed therein and penetrating the second substrate 7.

The insulating members 13 and 14 cover external surfaces of the holder substrate 11 and inner surfaces of the holes 6a and 7a.

An opening is formed by the hole 6a and the hole 7a communicating with each other and their inner surfaces being covered with the insulating members 13 and 14.

Furthermore, an opening is formed by the hole 6b and the hole 7b communicating with each other in the conductive contact holder 3.

In this embodiment, the openings are referred to as first to third openings 8-10 according to types of the conductive contacts 4 accommodated therein. Specifically, the opening that accommodates the signal conductive contact 15 is referred to as the first opening 8, the opening that accommodates the ground conductive contact 16 as the second opening 9, and the opening that accommodates the power supply conductive contact 17 as the third opening 10. The first opening 8 and the third opening 10 are through holes formed by the holes 6a and 7a, and the insulating members 13 and 14 cover inner surfaces of the first opening 8 and the third opening 10. The second opening 9 is a through hole formed by the holes 6b and 7b. Therefore, together with the insulating members 13 and 14 (a holding member), some of the holes 6a and 7a form the first opening 8 and the remaining (other) ones of the holes 6a and 7a form the third opening 10, as first holes. Furthermore, the holes 6b and 7b form the second opening 9, as a second hole.

These openings are each formed in a cylindrical shape so as to penetrate the conductive contact holder 3, and by being formed in such a shape, function as positioning means and guiding means for the conductive contacts accommodated therein. The holes 6a, 6b, 7a, and 7b are formed by performing etching or punching on the first substrate 6 and the second substrate 7 respectively, or by performing processing using, for example, a laser, an electron beam, an ion beam, wire electrical discharge machining, or a drill.

The holes 6a and 7a are each formed to have an inner diameter larger than the inner diameter of the second opening 9 (the holes 6b and 7b) by an amount corresponding to the insulating member 13-14 formed on the inner surface thereof. This is because the holes 6b and 7b are each formed to have a diameter substantially equal to the outer diameter of the ground conductive contact 16 to thereby provide a guiding function and a grounding function. The holes 6aand 7a, on the other hand, have functions of accommodating the signal conductive contact 15 and the power supply conductive contact 17 via the insulating members 13 and 14. As long as the diameter of the second opening 9 (holes 6b and 7b) is a diameter capable of holding the ground conductive contact 16, the diameter of the second opening 9 may be different from the outer diameter of the ground conductive contact 16.

Furthermore, the first opening 8, the second opening 9, and the third opening 10 are each formed to have smaller inner diameters near upper and lower external surfaces of the holder substrate 11 to prevent the conductive contacts from coming off. Because the conductive contacts each have flange portions for preventing the conductive contacts from coming off, the first opening 8, the second opening 9, and the third opening 10 each have a stepped shape in which the inner diameter is reduced near the upper and lower surfaces so that the flange portions abut against the openings. Since the configuration in which the inner diameters are reduced near both the upper and lower surfaces is adopted, a structure in which the holder substrate 11 is divided into the first substrate 6 and the second substrate 7 is adopted to enable the conductive contacts to be accommodated in the first opening 8 and other openings during manufacturing.

By being formed on the inner surfaces of the holes 6a and 7a, the insulating members 13 and 14 have a function of electrically insulating the signal conductive contact 15 and the power supply conductive contact 17 from the holder substrate 11. Furthermore, by being formed also on the external surfaces of the holder substrate 11, the insulating members 13 and 14 have a function of electrically insulating the semiconductor integrated circuit 1 and the circuit board 2 from the holder substrate 11. The insulating member 13 covers external surfaces of the first substrate 6, the external surfaces excluding a surface thereof that is in contact with the second substrate 7. The insulating member 14 covers external surfaces of the second substrate 7, the external surfaces excluding a surface thereof that is in contact with the first substrate 6. Accordingly, the holder substrate 11 is covered by the insulating members 13 and 14 on its upper surface, lower surface, and side surfaces connected to the upper and lower surfaces.

In this embodiment, the materials forming the insulating members 13 and 14 and the thicknesses of the insulating members 13 and 14 are not particularly limited, and the insulating members 13 and 14 may be formed using any material having any thickness that enables its insulating function to be achieved sufficiently. The insulating members 13 and 14 constitute a holding member for the signal conductive contact 15 or the power supply conductive contact 17, and may, for example, be formed by injection molding or be formed as a film by coating. In this case, the insulating members 13 and 14, as the holding member for the signal conductive contact 15 or the power supply conductive contact 17, have stepped portions, with which the flange portions of the conductive contact engage, at both end portions thereof in the penetration direction. Furthermore, cylindrical insulating members on the inner surfaces of the first opening 8 and third opening 10 and plate-like insulating members on the external surfaces of the holder substrate 11 may be arranged either integrally or separately.

In the example described with respect to the embodiment, the insulating members 13 and 14 are formed as an integrated configuration of insulating members and a holding member.

A coaxial structure is formed by causing the central axis of the signal conductive contact 15 to coincide with the central axis of the inner surface of the holder substrate 11 (holes 6a and 7a).

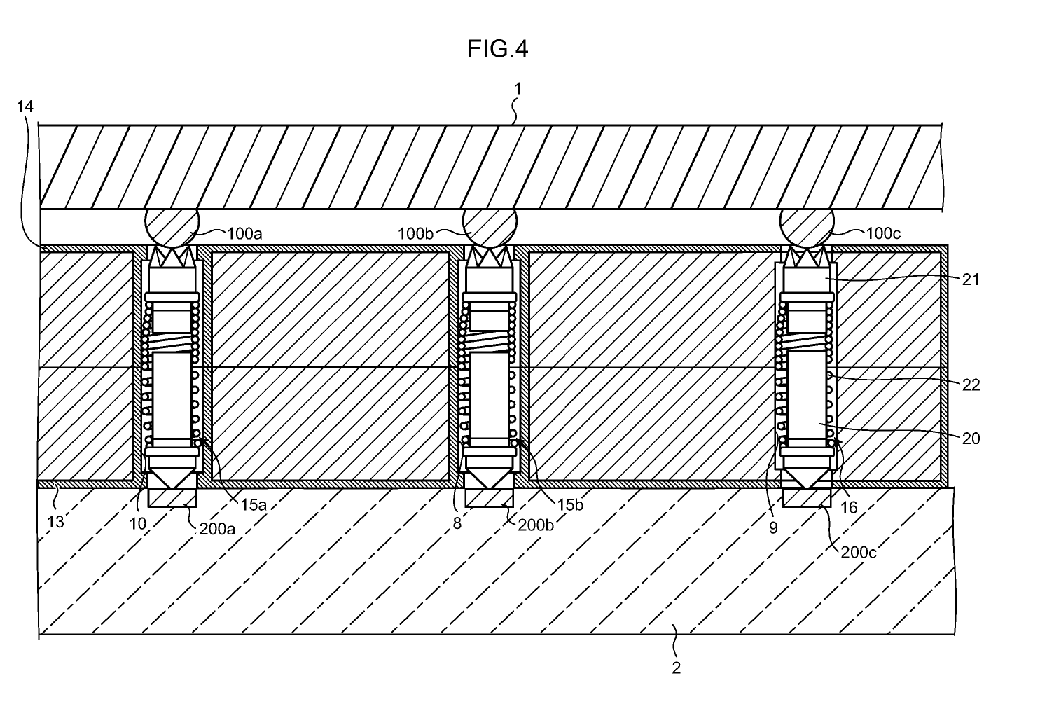

Electrical interaction between conductive contacts and the conductive contact holder 3 during testing of a semiconductor integrated circuit, in the conductive contact unit according to the embodiment will be described next. FIG. 4 is a schematic diagram illustrating electrical interaction between the conductive contacts 4 and the conductive contact holder 3 during use of the conductive contact unit according to the embodiment. To facilitate description of advantages of the conductive contact unit, FIG. 4 illustrates a configuration in which a signal conductive contact 15a and a signal conductive contact 15b are adjacent to each other.

Electrical action at the ground conductive contact 16 will be described first. The ground conductive contact 16 in this embodiment is configured not only to supply a potential from the circuit board 2 to the semiconductor integrated circuit 1 via electrodes 100c and 200c, but also to receive a potential from the holder substrate 11 and supply a ground potential to the semiconductor integrated circuit 1. That is, as illustrated in FIG. 3, the holder substrate 11 is configured such that: no insulating members are formed on the inner surface of the second opening 9 that accommodates the ground conductive contact 16; and the inner surface of the second opening 9 directly contacts the outer peripheral surface of the ground conductive contact 16, specifically, as illustrated in FIG. 4, the spring member 22 flexed by the contraction operation. Because the holder substrate 11 is formed of a conductive material as described above, the ground conductive contact 16 and the holder substrate 11 are then electrically connected. Therefore, because internal charges are able to freely move between the ground conductive contact 16 and the holder substrate 11, the potential supplied by the ground conductive contact 16 has a value equal to that of the potential of the holder substrate 11.

The signal conductive contacts 15a and 15b respectively receive electrical signals generated in the circuit board 2 from electrodes 200a and 200b, and input and output received electrical signals from and to the semiconductor integrated circuit 1 via electrodes 100a and 100b.

Furthermore, the power supply conductive contact 17 receives power for power supply generated in the circuit board 2 from an electrode of the circuit board 2, and supplies the received power to the semiconductor integrated circuit 1 via an electrode of the semiconductor integrated circuit 1.

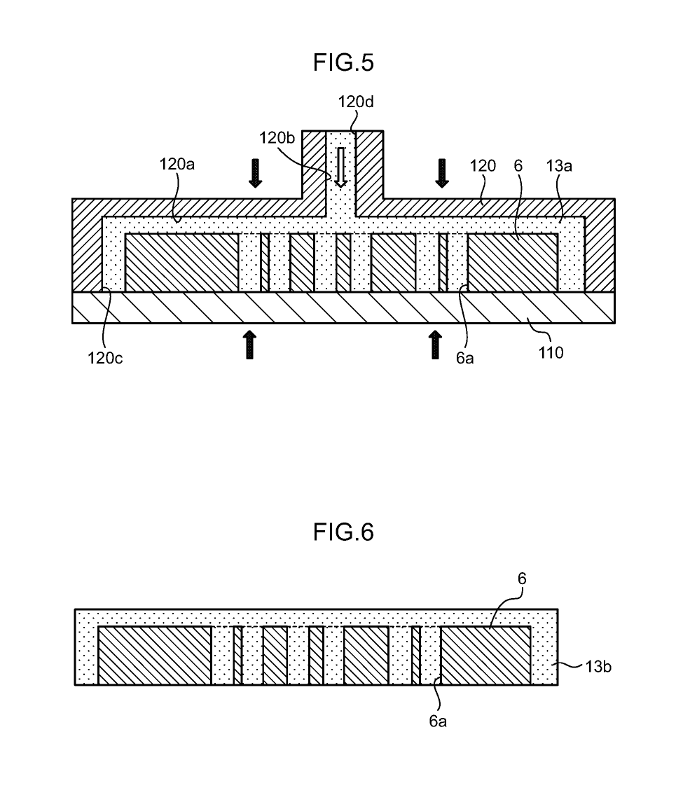

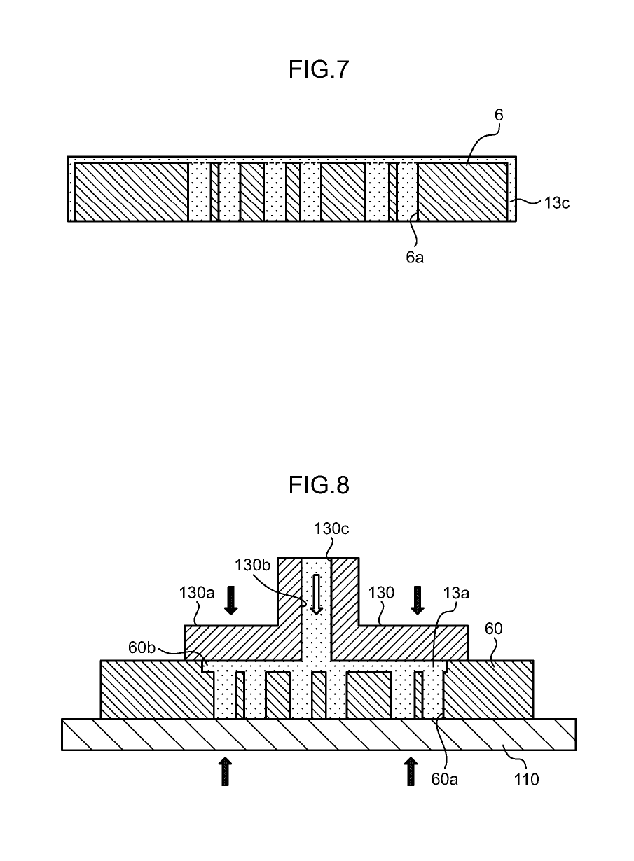

A method of manufacturing the conductive contact holder according to the embodiment, and a method of manufacturing a conventional conductive contact holder will be described next by reference to FIGS. 5-9. FIGS. 5-7 are diagrams for description of the method of manufacturing the conductive contact holder according to the embodiment. FIGS. 5-9 illustrate a process for one substrate (the first substrate 6) of the substrates constituting the holder substrate 11, but the other substrate (the second substrate 7) is manufactured by a similar process.

Firstly, holes for accommodating the conductive contacts 4 have been formed in the substrates (the first substrate 6 and the second substrate 7) constituting the holder substrate 11. For example, FIG. 5 illustrates an example in which a plurality of holes 6a are formed, but a hole or holes 6b may also be formed. Sizes of the holes 6a may be respectively set according to the types of conductive contacts 4 accommodated therein.

The process for the first substrate 6 will be described hereinafter, but a similar process is performed for the second substrate 7.

A first mold 110 and a second mold 120 are disposed on the first substrate 6 having the holes 6a formed therein.

The first mold 110 is formed in a flat plate shape, and the first substrate 6 is placed on the first mold 110.

The second mold 120 includes an accommodation portion 120a to accommodate the first substrate 6, and an introduction portion 120b extending from the accommodation portion 120a and into which a liquid molding material is to be introduced. Furthermore, the accommodation portion 120a is provided with a first hollow portion 120c that forms a hollow space to accommodate the first substrate 6. The introduction portion 120b is provided with a second hollow portion 120d that forms a hollow space, one end of the hollow space communicating with the first hollow portion 120c, the other end of the hollow space communicating with the outside.

As illustrated in FIG. 5, the first substrate 6 is accommodated in a hollow space formed by the first mold 110 and the first hollow portion 120c of the second mold 120. A distance between a wall surface of the first hollow portion 120c and an external surface of the first substrate 6 is equal to or larger than the thickness of the insulating member 13. An example in which the distance between the first hollow portion 120c and the first substrate 6 is larger than the thickness of the insulating member 13 will be described with respect to the embodiment.

After the first substrate 6 has been disposed in the molds, a liquid insulating material 13a is introduced into the first hollow portion 120c through the second hollow portion 120d. The first hollow portion 120c and the second hollow portion 120d are then filled with the insulating material 13a and the holes 6a are also filled with the insulating material 13a.

Thereafter, the insulating material 13a is solidified. A solidified insulating base material 13b is thereby obtained. This insulating base material 13b covers, in addition to the inner surfaces of the holes 6a, the external surfaces of the first substrate 6, the external surfaces excluding an outer surface thereof that is in contact with the first mold 110.

After the insulating base material 13b has been formed, surfaces of the insulating base material 13b are machined to adjust the thickness of the insulating base material 13b. An insulating member 13c is formed by this machining.

If the insulating base material has the designed thickness, the machining may be omitted.

After the insulating member 13c has been formed, by performing perforation at positions in the insulating member 13c, the positions corresponding to the holes 6a, openings that constitute some of the first opening 8 or the third opening 10 are formed. In a portion at which the second opening 9 is formed, a hole 6b is formed at a predetermined position in the first substrate 6, the second opening 9 being an opening through which the ground conductive contact 16 is inserted.

With respect to the above-described process, the example in which the insulating material is solidified by injection molding and thereafter perforation corresponding to the opening is performed has been described above, but without being limited to this example, for example, a columnar portion corresponding to an opening may be formed in a first mold and the above-described perforation may be omitted. Furthermore, without being limited to injection molding, the insulating member may be provided on the substrate by applying an insulating material to the substrate and solidifying the insulating material, or by attaching a sheet-shaped insulating member to the substrate.

A conductive contact holder is then formed by joining the first substrate 6, on which the insulating member 13 has been disposed, and the second substrate 7, on which the insulating member 14 has been disposed, with their exposed surfaces facing each other. A hole (opening) in the first substrate 6 and a hole (opening) in the second substrate 7 then communicate with each other, thereby forming one of the first opening 8, the second opening 9, and the third opening 10 described above. They may be joined by fastening by screwing, bonding using an adhesive, or welding.

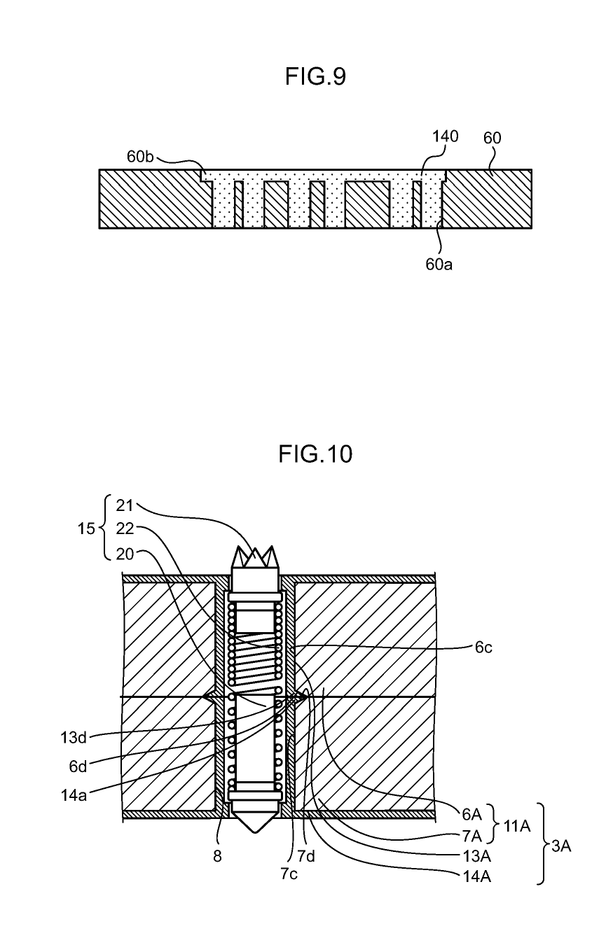

FIGS. 8 and 9 are diagrams for description of the method of manufacturing the conventional conductive contact holder.

Firstly, a first mold 110 and a third mold 130 are disposed on a first substrate 60. A plurality of holes 60a through which conductive contacts are inserted, and a recess 60b provided at one through direction end of the holes 60a are formed in the first substrate 60, the recess 60b having a bottomed shape and being sized such that all the holes 60a communicate therewith.

The first substrate 60 is placed on the first mold 110 such that the first mold 110 contacts a surface of the first substrate 60, the surface being opposite to a surface on which the recess 60b is formed.

Furthermore, the third mold 130 includes a first portion 130a that covers the recess 60b in the first substrate 60, and a second portion 130b which extends from the first portion 130a and into which a liquid molding material is introduced. Furthermore, the third mold 130 is provided with a hollow portion 130c penetrating therethrough from the first portion 130a to the second portion 130b.

After the molds have been disposed on the first substrate 60, a liquid insulating material 13a is introduced into the holes 60a and the recess 60b, through the hollow portion 130c. The holes 60a and the recess 60b are then filled with the insulating material 13a.

Thereafter, the insulating material 13a is solidified. A solidified insulating member 140 is thereby obtained. After the insulating member 140 has been formed, openings are formed by performing perforation at positions corresponding to the holes 60a in the insulating member 140.

A conductive contact holder is then formed by joining the first substrate 60, on which the insulating member 140 has been disposed, and a second substrate, on which an insulating member has been similarly disposed, with their exposed surfaces facing each other. The holes (openings) in the first substrate 60 and the holes (openings) in the second substrate then communicate with each other, thereby forming openings to accommodate conductive contacts. They may be joined by fastening by screwing, bonding using an adhesive, or welding.

As described above, the conventional conductive contact holder does not have an insulating member formed on at least the entire upper surface and external side surfaces of the substrate.

In the above described embodiment, the insulating members 13 and 14 cover all external surfaces of the holder substrate 11 and the insulating performance of the conductive contact holder 3 is thus able to be improved. In the embodiment, improving the insulating performance of the conductive contact holder 3 by means of the insulating members 13 and 14 enables high frequency characteristics to be improved. Since insulating members 13 and 14 cover all the external surfaces of the holder substrate 11, handling equivalent to that of a general resin probe block is enabled.

For example, in a case where sheet-like insulating members are attached to respective surfaces, gaps are generated at joints between the insulating members, but in this embodiment, as described above, by disposing insulating members on substrates by injection molding, such joints are not generated in the injection molding and insulation performance is thus able to be improved.

A first modified example of the embodiment will be described next by reference to FIG. 10. FIG. 10 is a partial sectional view illustrating a configuration of a conductive contact holder according to the first modified example of the embodiment. In FIG. 10, the same reference signs are assigned to components that are the same as the components according to the embodiment described above.

A conductive contact unit according to the first modified example includes: a circuit board 2 including a circuit that generates a signal to be supplied to a semiconductor integrated circuit 1; a conductive contact holder 3A arranged on the circuit board 2 and including predetermined openings; and conductive contacts 4 accommodated in the openings of the conductive contact holder 3. The conductive contact holder 3A includes a holder substrate 11A and insulating members 13A and 14A. The holder substrate 11A includes a first substrate 6A and a second substrate 7A.

As illustrated in FIG. 10, a hole 6c through which a signal conductive contact 15 or a power supply conductive contact 17 of the conductive contacts 4 is inserted is formed in the first substrate 6A according to the first modified example. In the hole 6c, a notch 6d is formed at an end portion that comes into contact with the second substrate 7A out of both end portions in the penetration direction.

In the first substrate 6A, the above described hole 6b is formed as a hole through which a ground conductive contact 16 is inserted.

Furthermore, a hole 7c through which the signal conductive contact 15 or the power supply conductive contact 17 of the conductive contacts 4 is inserted is formed in the second substrate 7A. In the hold 7c, a notch 7d is formed at an end portion that comes into contact with the first substrate 6A out of both end portions in the penetration direction.

The insulating member 13A is formed by, for example, injection molding described above, and covers the inner surface of the hole 6c and external surfaces of the first substrate 6A, the external surfaces excluding a surface thereof facing the second substrate 7A. The insulating member 13A is formed such that, at the portion where the notch 6d is formed, the diameter defined by its inner peripheral surface is uniform. Therefore, at the portion where the notch 6d is formed, the insulating member 13A has a projection 13d having a hook-like shape conforming to the shape of the notch 6d.

Similarly to the insulating member 13A, the insulating member 14A covers the inner surface of the hole through which the signal conductive contact 15 or the power supply conductive contact 17 is inserted and external surfaces of the second substrate 7A, the external surfaces excluding a surface thereof facing the first substrate 6A. The insulating member 14A is formed such that, at the portion where the notch 7d is formed, the diameter defined by its inner peripheral surface is uniform. Therefore, at the portion where the notch 7d is formed, the insulating member 14A has a projection 14a having a hook-like shape conforming to the shape of the notch 7d.

In the conductive contact holder 3A, for example, a projection is formed by contact between the projections 13d and 14a of the insulating members 13A and 14A forming a first opening 8.

A configuration in which only one of the notches 6d and 7d is formed may be adopted instead. In this case, a projection in the conductive contact holder 3A is formed of only a projection of the one for which the notch is formed.

In the above described first modified example, similarly to the embodiment, all the external surfaces of the holder substrate 11A are covered by the insulating members 13A and 14A, and insulating performance of the conductive contact holder 3A is thus able to be improved even more. According to the first modified example, increasing the insulating performance of the conductive contact holder 3 by means of the insulating members 13A and 14A enables high frequency characteristics to be improved.

Furthermore, in the first modified example, the notches are formed at the end portions of the holes through which the signal conductive contact 15 or the power supply conductive contact 17 is inserted in the first substrate 6A and the second substrate 7A, and the insulating members each form the projection having the hook-like shape conforming to the shape of the notch. According to the first modified example, the projections of the insulating members are engaged with the holder substrate 11A and the insulating members are less likely to be detached from the holder substrate 11A, as compared with the conductive contact holder 3 according to the embodiment described above.

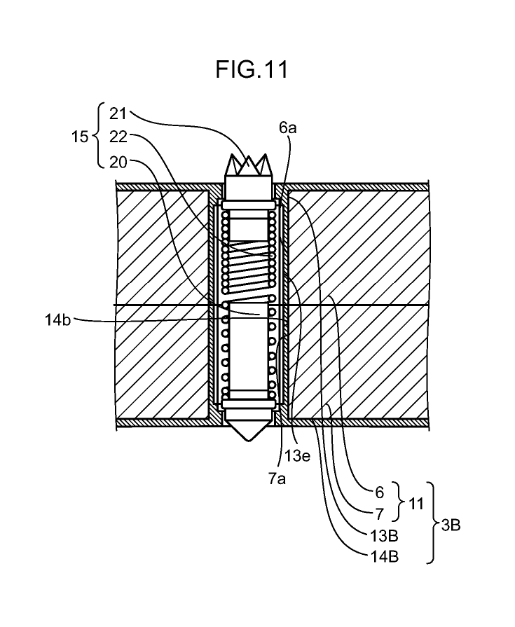

A second modified example of the embodiment will be described next by reference to FIG. 11. FIG. 11 is a partial sectional view illustrating a configuration of a conductive contact holder according to the second modified example of the embodiment. In FIG. 11, the same reference signs are assigned to components that are the same as the components according to the embodiment described above.

A conductive contact unit according to the second modified example includes: a circuit board 2 including a circuit that generates a signal to be supplied to a semiconductor integrated circuit 1; a conductive contact holder 3B arranged on the circuit board 2 and including predetermined openings; and conductive contacts 4 accommodated in the openings of the conductive contact holder 3B. The conductive contact holder 3B includes a holder substrate 11 and insulating members 13B and 14B.

The insulating member 13B is formed by, for example, the above described injection molding and covers the inner surface of a hole 6a and external surfaces of a first substrate 6, the external surfaces excluding a surface thereof facing a second substrate 7. The insulating member 13B has a recess 13e formed in part of its inner surface, and a central portion thereof in the penetration direction forms a hollow space having a larger diameter compared to an end portion thereof in the penetration direction.

Similarly to the insulating member 14B, the insulating member 14B is formed by, for example, the above described injection molding, and covers the inner surface of the hole 7a and external surfaces of the second substrate 7, the external surfaces excluding a surface thereof facing the first substrate 6. The insulating member 14B has a recess 14b formed in part of its inner surface, and a central portion thereof in the penetration direction forms a hollow space having a larger diameter compared to an end portion thereof in the penetration direction.

The conductive contact holder 3B has a recess formed by contact between the recesses 13e and 14b in the insulating members 13B and 14B forming, for example, a first opening 8.

The recesses 13e and 14b forming the recess may be provided over the same length or over lengths different from each other in the penetration direction. A recess may be formed in only one of the insulating members 13B and 14B instead.

In the above described second modified example, similarly to the embodiment, all the external surfaces of the holder substrate 11 are covered by the insulating members 13B and 14B, and insulating performance of the conductive contact holder 3B is thus able to be improved even more. According to the second modified example, increasing the insulating performance of the conductive contact holder 3 by means of the insulating members 13B and 14B enables high frequency characteristics to be improved.

Furthermore, because the recesses 13e and 14b are respectively formed in the insulating members 13B and 14B in the second modified example, as compared with the openings according to the above described embodiment, the hollow space in the opening is larger and dielectric loss is thereby able to be reduced even more.

As described above, the present disclosure may include various embodiments not described herein, and various design changes may be made without departing from the technical ideas defined by the claims. For example, the example in which the conductive contact unit is configured to include the signal conductive contact, the ground conductive contact, and the power supply conductive contact has been described above, but any conductive contact unit including at least a signal conductive contact may be adopted, and a probe having another shape and/or a conductive fastening member may be used for power supply and grounding functions thereof.

As described above, a conductive contact holder and a conductive contact unit, according to the present disclosure are suitable for improving high frequency characteristics.

The present disclosure has an effect of enabling improvement in high frequency characteristics.

All examples and conditional language recited herein are intended for pedagogical purposes of aiding the reader in understanding the disclosure and the concepts contributed by the inventor to further the art, and are not to be construed as limitations to such specifically recited examples and conditions, nor does the organization of such examples in the specification relate to a showing of the superiority and inferiority of the disclosure. Although the embodiment has been described in detail, it should be understood that the various changes, substitutions, and alterations could be made hereto without departing from the spirit and scope of the disclosure.

What is claimed is:

1. A conductive contact unit, comprising:
a signal conductive contact configured to input and output signals from and to a predetermined circuit structure; and
a conductive contact holder configured to accommodate the signal conductive contact and form, together with the signal conductive contact, a coaxial structure, wherein
the conductive contact holder includes:
a holder substrate that is conductive and has, formed therein, a hole through which the signal conductive contact is insertable;
a holding member that is accommodated in the hole, has, formed therein, a holding hole to hold the signal conductive contact, and is insulating; and
an insulating member configured to cover all external surfaces of the holder substrate.

2. The conductive contact unit according to claim 1, wherein the insulating member is molded integrally with the holding member.

3. The conductive contact unit according to claim 1, wherein
the holder substrate has a first substrate and a second substrate stacked on each other,
in the hole, a first notch is formed in the first substrate on a side of a surface contacting the second substrate,
in the hole, a second notch is formed in the second substrate on a side of a surface contacting the first substrate, and
the holding member has, formed therein, a projection configured to engage with the first notch and the second notch.

4. The conductive contact unit according to claim 1, wherein the holding member has a recess formed in a central portion thereof in a penetration direction.

5. The conductive contact unit according to claim 1, further comprising:
a ground conductive contact configured to supply a ground potential to the predetermined circuit structure; and
a power supply conductive contact configured to supply power to the predetermined circuit structure, wherein
the conductive contact holder has:
a first opening configured to accommodate the signal conductive contact;
a second opening configured to accommodate the ground conductive contact; and
a third opening configured to accommodate the power supply conductive contact,
the first opening has, formed therein, a first holding member on a surface of some of first holes of a plurality of the holes in the holder substrate, the first holding member being insulating,
the third opening has, formed therein, a second holding member on a surface of other some of the first holes of the holes in the holder substrate, the second holding member being insulating, and
the second opening is formed of an inner surface of a second hole of the holes in the holder substrate.
